(19) United States
(12) Patent Application Publication
(10) Pub. No.: US 2025/0038029 A1
(43) Pub. Date: Jan. 30, 2025

(54) POSTURE TURNING APPARATUS AND SUBSTRATE PROCESSING APPARATUS INCLUDING THE SAME

(71) Applicant: SCREEN Holdings Co., Ltd., Kyoto (JP)

(72) Inventors: Akihiro IWASAKI, Kyoto (JP); Shinichi TANIGUCHI, Kyoto (JP)

(21) Appl. No.: 18/779,437

(22) Filed: Jul. 22, 2024

(30) Foreign Application Priority Data
Jul. 25, 2023 (JP) 2023-120893

(51) Int. Cl. H01L 21/677; H01L 21/67

(52) U.S. Cl. CPC H01L 21/67781; H01L 21/67057

(57) ABSTRACT

A posture turning apparatus for turning a posture of a plurality of substrates, including: an reversing chuck that holds the substrates; an opening/closing drive mechanism that drives the reversing chuck in a radial direction of the substrates between an open position for transferring the substrates to and from the reversing chuck and a holding position for holding the substrates by the reversing chuck; a rotary drive mechanism that drives the reversing chuck about a horizontal axis for turning the posture of the substrates from a vertical posture to a horizontal posture; a control unit that operates the rotary drive mechanism so that processing surfaces of the substrates face upward when turning the posture of the substrates from the vertical posture to the horizontal posture after operating the opening/closing drive mechanism to cause the reversing chuck to hold the plurality of substrates in a vertical posture.

### BACKGROUND OF THE INVENTION

### (1) Field of the Invention

The present invention relates to a posture turning apparatus that performs predetermined processing on a substrate such as a semiconductor substrate, a substrate for a flat panel display (FPD) such as a liquid crystal display or an organic electroluminescence (EL) display device, a glass substrate for a photomask, or a substrate for an optical disk, and a substrate processing apparatus including the posture turning apparatus.

### (2) Description of the Related Art

Conventionally, this type of apparatus includes a batch type module, a single wafer type module, and a posture turning module. For example, JP 2016-502275 A is referred to. The batch type module collectively processes a plurality of substrates. The single wafer type module performs processing on each substrate. In general, the drying processing by the single wafer type module has a small space of a processing atmosphere in which the substrate is affected and high particle performance as compared with the drying processing by the batch type module. Therefore, the single wafer type module is more likely to enhance the drying performance than the batch type module. Therefore, for example, the etching processing and the rinsing processing may be performed by the batch type module, and then the drying processing may be performed by the single wafer type module.

In the batch type module, processing is performed in a state in which a plurality of substrates are in a vertical posture. On the other hand, in the single wafer type module, the processing is performed in a state where the substrate is in a horizontal posture. Therefore, the substrate in the vertical posture that has been processed by the batch type module is turned to the horizontal posture by the posture turning module before being transported to the single wafer type module.

Specifically, the posture turning module includes: a chuck having a both-outermost-surfaces support portion that abuts and supports both outermost surfaces of the substrates, and a lower-end-surface support portion that abuts and supports the lower side of end surfaces orthogonal to both side surfaces on the substrate surface; and a rotating mechanism that rotates the chuck by 90 degrees to one side about a horizontal axis. The rotating mechanism rotates the chuck by 90 degrees about the horizontal axis such that the lower-end-surface support portion is positioned on the opposite side to the direction in which the robot that transfers the substrates one by one to the single wafer type module is disposed in plan view. After the chuck is rotated by the rotating mechanism, the robot can receive the substrate from a direction in which the lower-end-surface support portion is not disposed in the chuck.

However, the conventional example having such a configuration has the following problems.

That is, the conventional device allows the chuck to rotate only 90 degrees in one direction about the horizontal axis. In such a configuration, for example, when processing surfaces of the plurality of substrates are directed to the robot side in the vertical posture, it is not possible to turn the posture of the substrates into the horizontal posture with the processing surfaces facing upward. That is, there is the problem that posture turning of the plurality of substrates can be performed only when the processing surfaces of the plurality of substrates are directed to the side opposite to the robot side in the vertical posture.

In the batch type module, in order to improve throughput, a plurality of substrates constituting one lot and a plurality of substrates constituting another lot are combined into one, and processing may be performed in units of batch lots. In such a case, there are two types of surface matching, that is, face-to-face matching (also referred to as “face-to-face”) and face-to-back matching (also referred to as “face-to-back”), according to a way of matching the processing surfaces of the lots, i.e., to which posture the processing surfaces are matched to configure the batch lot. Since the posture turning module of the conventional example can be rotated only in one direction, the posture turning for the lot in which the processing surfaces are reversed cannot be properly performed such that the processing surfaces are directed upward.

### SUMMARY OF THE INVENTION

The present invention has been made in view of such circumstances, and an object thereof is to provide a posture turning apparatus that can properly posture turning regardless of a posture of a processing surface of a substrate, and a substrate processing apparatus including the posture turning apparatus.

In order to achieve such an object, the present invention has the following configuration.

That is, the present invention is a posture turning apparatus that turns a posture of a plurality of substrates, the apparatus including the following elements: an reversing chuck that holds the plurality of substrates; an opening/closing drive mechanism that drives the reversing chuck in a radial direction of the substrates between an open position for transferring the plurality of substrates to and from the reversing chuck and a holding position for holding the plurality of substrates by the reversing chuck; a rotary drive mechanism that drives the reversing chuck about a horizontal axis in order to turn the posture of the plurality of substrates from a vertical posture to a horizontal posture; a control unit that operates the rotary drive mechanism so that processing surfaces of the plurality of substrates face upward, when turning the posture of the plurality of substrates from the vertical posture to the horizontal posture after operating the opening/closing drive mechanism so as to cause the reversing chuck to hold the plurality of substrates in a vertical posture.

According to the present invention, the control unit operates the opening/closing drive mechanism to cause the reversing chuck to hold the plurality of substrates in the vertical posture. Thereafter, when turning the posture of the plurality of substrates from the vertical posture to the horizontal posture, the control unit operates the rotary drive mechanism so that the processing surfaces of the plurality of substrates face upward. Therefore, regardless of the posture of the processing surfaces of the substrates, posture turn can be properly performed such that the processing surfaces of the plurality of substrates face upward.

Note that the processing surfaces of the substrates in the present invention refers to the surfaces to be processed after the posture is turned into the horizontal posture in posture turning apparatus. The processing surfaces are the surfaces facing upward when the substrates are placed in the horizontal posture.

Further, in the present invention, it is preferable that the control unit operates the rotary drive mechanism so as to rotate in one direction or the other direction opposite to the one direction according to the posture of the processing surfaces of the plurality of substrates.

The plurality of substrates in the vertical posture have the processing surfaces directed in one direction or the other direction. Therefore, the control unit operates the rotary drive mechanism so as to rotate by a predetermined angle in the other direction that is the opposite side of the one direction or the one direction that is the opposite side of the other direction according to the direction of the processing surface, whereby the processing surfaces of the plurality of substrates can be directed upward.

In the present invention, it is preferable that the control unit operates the rotary drive mechanism so as to rotate only in one direction according to the posture of the processing surfaces of the plurality of substrates.

The plurality of substrates in the vertical posture have the processing surfaces directed in one direction or the other direction. Therefore, the control unit can cause the processing surfaces of the plurality of substrates to face upward by operating the rotary drive mechanism to rotate only in one direction or the other direction. Since the rotation is performed only in any direction, the rotation control by the control unit can be easily performed.

In the present invention, it is preferable that the reversing chuck holds only both outermost surfaces of the plurality of substrates in a direction orthogonal to a direction in which the plurality of substrates are transferred.

When turning the posture of the plurality of substrates from the vertical posture to the horizontal posture, the reversing chuck does not interfere during transfer even if the substrates are rotated in any direction. Therefore, the subsequent transfer operation can be smoothly performed.

Further, in the present invention, it is preferable that the control unit operates the rotary drive mechanism according to a recipe that defines how to process the plurality of substrates.

Since the control unit operates the rotary drive mechanism according to the recipe, the rotary drive mechanism can be appropriately operated for each of the plurality of substrates.

Further, it is preferable in the present invention that for a batch lot configured by matching a certain plurality of substrates and another plurality of substrates, the control unit operates the rotary drive mechanism according to, among the above-described recipes, a way of matching the processing surfaces, i.e., to which posture the processing surfaces are matched.

The control unit operates the rotary drive mechanism according to, among the recipes, a way of matching the processing surfaces. Therefore, since the control unit recognizes the posture of the processing surfaces of the plurality of substrates, the control unit can appropriately operate the rotary drive mechanism for each of the plurality of substrates.

The present invention is a substrate processing apparatus that processes a substrate, the apparatus including the following elements: a batch type processing unit that collectively processes a plurality of substrates in a vertical posture; a single wafer type processing unit that processes one substrate in a horizontal posture; a posture turning unit that turns the vertical posture to the horizontal posture of the plurality of substrates processed by the batch type processing unit; a first transport unit that transports the plurality of substrates processed by the batch type processing unit to the posture turning unit; and a second transport unit that transports the plurality of substrates brought into a horizontal posture by the posture turning unit to the single wafer type processing unit; in which the posture turning unit includes: an reversing chuck that holds the plurality of substrates; an opening/closing drive mechanism that drives the reversing chuck in a radial direction of the substrates between an open position for transferring the plurality of substrates to and from the reversing chuck and a holding position for holding the plurality of substrates by the reversing chuck; and a rotary drive mechanism that drives the reversing chuck about a horizontal axis to turn the plurality of substrates from the vertical posture to the horizontal posture.

According to the present invention, the control unit operates the opening/closing drive mechanism to cause the reversing chuck to hold the plurality of substrates in the vertical posture after the batch type processing unit processes the plurality of substrates and before the single wafer type processing unit transports the plurality of substrates. Thereafter, when turning the posture of the plurality of substrates from the vertical posture to the horizontal posture, the control unit operates the rotary drive mechanism so that the processing surfaces of the plurality of substrates face upward. Therefore, regardless of the posture of the processing surfaces of the substrates, posture turn can be properly performed such that the processing surfaces of the plurality of substrates face upward.

### BRIEF DESCRIPTION OF THE DRAWINGS

For the purpose of illustrating the invention, there are shown in the drawings several forms which are presently preferred, it being understood, however, that the invention is not limited to the precise arrangement and instrumentalities shown.

FIG. 1 is a plan view showing an overall configuration of a substrate processing apparatus according to an embodiment;

FIG. 2 is a cross-sectional view taken along line A-A in FIG. 1;

FIGS. 3A and 3B are schematic diagrams for explaining a way of matching processing surfaces constituting a batch lot;

FIGS. 4A and 4B are schematic diagrams for explaining a way of matching processing surfaces constituting the batch lot;

FIG. 5 is a plan view illustrating a configuration of a 25-piece chuck and an reversing chuck;

FIG. 6 is a front view in a state where the reversing chuck is set to an open position;

FIG. 7 is a front view in a state where the reversing chuck is set to a holding position;

FIG. 8 is a front view illustrating a configuration of a posture turning tank and illustrating a state in which a substrate is held in a vertical posture;

FIG. 9 is a front view illustrating a configuration of the posture turning tank and illustrating a state in which a substrate is held in a horizontal posture;

FIG. 10 is a block diagram illustrating a control system;

FIGS. 11A to 11D are schematic diagrams illustrating an example of posture turn in a batch lot of face-to-face matching;

FIGS. 12A to 12D are schematic diagrams illustrating an example of posture turn in the batch lot of face-to-face matching;

FIGS. 13A to 13D are schematic diagrams illustrating another example of posture turn; and

FIG. 14 is a block diagram illustrating a modification of the control system.

### DESCRIPTION OF THE PREFERRED EMBODIMENTS

Hereinafter, preferred embodiments of the present invention will be described in detail with reference to the drawings.

Hereinafter, embodiments of the present invention will be described with reference to the drawings.

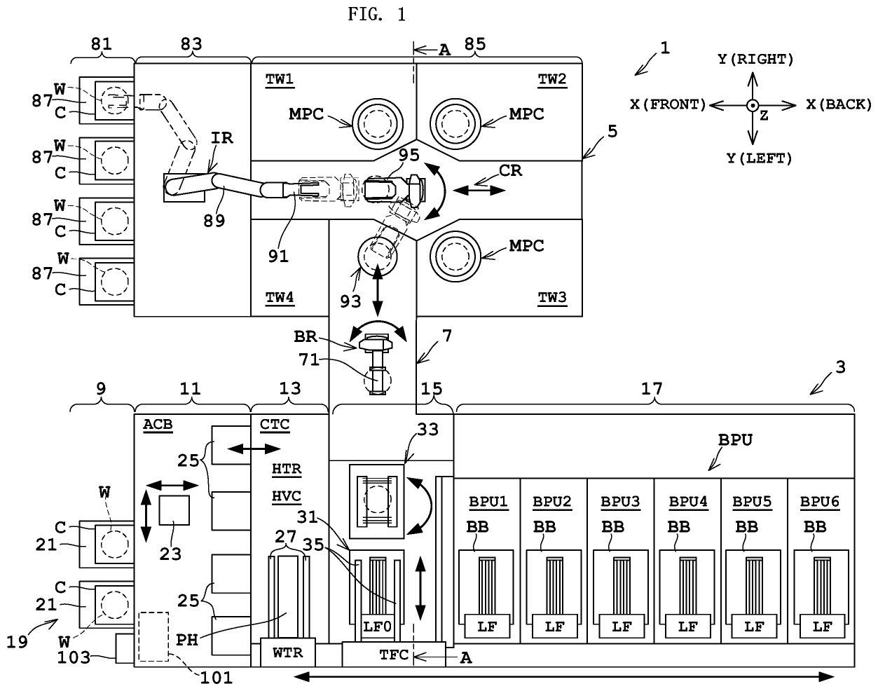

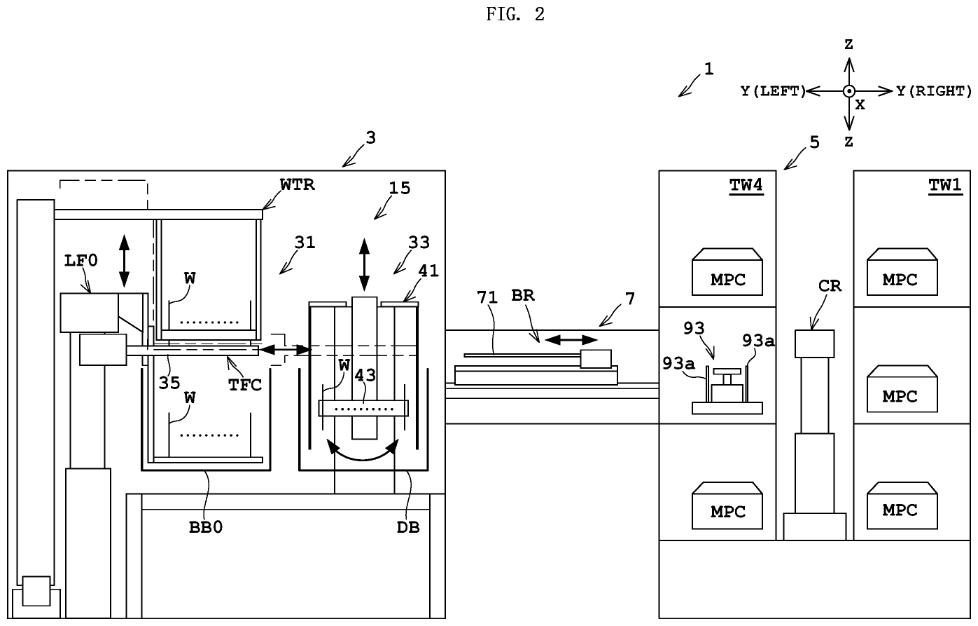

FIG. 1 is a plan view showing an overall configuration of a substrate processing apparatus according to an embodiment. FIG. 2 is a cross-sectional view taken along line A-A in FIG. 1.

### 1. Overall Configuration

A substrate processing apparatus 1 processes a substrate W. The substrate processing apparatus 1 performs, for example, chemical liquid processing, cleaning processing, drying processing, and the like on the substrate W. The substrate processing apparatus 1 adopts a processing method (so-called hybrid method) having both a batch type and a single wafer type. The batch type collectively processes a plurality of substrates W in a vertical posture. The single wafer type processes one substrate W in a horizontal posture.

The substrate processing apparatus 1 includes a batch type processing apparatus 3 and a single wafer type processing apparatus 5. In the present embodiment, the single wafer type processing apparatus 5 is disposed adjacent to the batch type processing apparatus 3. The batch type processing apparatus 3 and the single wafer type processing apparatus 5 are disposed apart from each other. The batch type processing apparatus 3 and the single wafer type processing apparatus 5 are coupled by a bridging unit 7.

### 2. Batch Type Processing Apparatus

The batch type processing apparatus 3 collectively processes a plurality of substrates W. The batch type processing apparatus 3 includes a loading block 9, a stocker block 11, a transfer block 13, a posture turning block 15, and a processing block 17.

In the present specification, for convenience, a direction in which the loading block 9, the stocker block 11, the transfer block 13, and the processing block 17 are arranged is referred to as a “front-back direction X”. The front-back direction X is horizontal. Of the front-back direction X, the direction from the stocker block 11 toward the loading block 9 is referred to as “front side”. A direction opposite to the front side is referred to as “back side”. A horizontal direction orthogonal to the front-back direction X is referred to as a “width direction Y”. One direction in the “width direction Y” is appropriately referred to as a “right side”. A direction opposite to the right side is referred to as “left side”. A direction perpendicular to the horizontal direction is referred to as a “vertical direction Z”. In each drawing, front, back, upper, lower, right, and left are appropriately shown for reference.

### 3. Loading Block

The loading block 9 includes a charging unit 19. The charging unit 19 is disposed at the front side X of the batch type processing apparatus 3. A carrier C stacks and stores the plurality of (for example, 25-sheets) substrates W in the vertical direction Z at constant intervals in the horizontal posture. In the carrier C, a plurality of grooves (not illustrated) for accommodating the substrates W one by one are formed with the surfaces of the substrates W separated from each other. As the carrier C, for example, there is a front opening unify pod (FOUP). The FOUP is a sealed container. The carrier C may be an open type container and may be of any type. The charging unit 19 includes, for example, two placing tables 21 on which the carrier C is placed. The two placing tables 21 are arranged, for example, along the width direction Y. The charging unit 19 is also referred to as a load port.

### 4. Stocker Block

The stocker block 11 is disposed adjacent to the back side X of the loading block 9. The stocker block 11 includes a transport storage unit ACB. The transport storage unit ACB includes a transport mechanism 23 and a shelf 25.

The transport mechanism 23 transports the carrier C. The transport storage unit ACB includes a plurality of shelves 25. The shelf 25 includes one on which the carrier C is simply temporarily placed and one on which the carrier C is placed for transfer between a first transport mechanism HTR. The transport storage unit ACB takes in the carrier C storing the unprocessed substrate W from the charging unit 19 and places the carrier C on the shelf 25. The transport storage unit ACB transports and places the carrier C on the transfer shelf 25 according to the schedule that defines the order of processing. The transport storage unit ACB transports and places the carrier C, which has been placed on the transfer shelf 25 and has become empty, on the shelf 25. The transport storage unit ACB carries out the empty carrier C placed on the shelf 25 to the placing table 21 according to the availability of the placing table 21. The empty carrier C is transported to the single wafer type processing unit 5. In the empty carrier C transported to the single wafer type processing unit 5, for example, the substrate W that has been stored in the carrier C before processing and has been processed is stored in the single wafer type processing unit 5.

### 5. Transfer Block

The transfer block 13 is disposed adjacent to the back side X of the stocker block 11. The transfer block 13 includes a transfer mechanism CTC. The transfer mechanism CTC includes the first transport mechanism HTR, a turning mechanism HVC, a pusher PH, and a second transport mechanism WTR.

The first transport mechanism HTR is disposed at the right side Y of the back side X of the transport storage unit ACB. The first transport mechanism HTR collectively transports the plurality of substrates W. In other words, the first transport mechanism HTR includes a plurality of hands (not illustrated). One hand supports one substrate W. The first transport mechanism HTR can also transport only one substrate W. The first transport mechanism HTR collectively takes out a plurality of substrates W (for example, 25-sheets) from the carrier C placed on the transfer shelf 25 in the transport storage unit ACB, and transports the substrates W to the turning mechanism HVC in the horizontal posture. At this time, the turning mechanism HVC orientates the posture of the substrate W from the horizontal posture to the vertical posture.

The turning mechanism HVC and the pusher PH are sequentially arranged in the left side Y of the first transport mechanism HTR. The turning mechanism HVC transfers the plurality of substrates W to the pusher PH. After receiving the plurality of substrates W from the turning mechanism HVC, the pusher PH moves to the second transport mechanism WTR in the width direction Y. At that time, the turning mechanism HVC and the pusher PH assemble a batch lot or release a batch lot. The pusher PH transfers the plurality of substrates W to the second transport mechanism WTR.

For example, the transfer mechanism CTC combines the plurality of substrates W constituting one lot extracted from one carrier C and the plurality of substrates W constituting another lot extracted from another carrier C as one batch lot. This is the assembly of the batch lot. The batch lot includes twice as many substrates W as one lot. In the batch lot, each substrate W of another lot is arranged so as to be adjacent to each substrate W of one lot. That is, each substrate W of one lot is arranged in odd-numbered order, and each substrate W of the other one lot is arranged in even-numbered order. Usually, the interval between the plurality of substrates W extracted from the carrier C is the same as that of the carrier C. This is called full pitch. In one batch lot, for example, the interval between the plurality of substrates W is half the full pitch. This is called half pitch. One lot and the other lot are combined as described above, but there are two types of batch lots, that is, face-to-face matching (also referred to as face to face) and face-to-back matching (also referred to as face to back) depending on how they are matched. How to combine the lots is determined by the operation of the pusher PH. In the following description, the plurality of substrates W are referred to as a lot, but in a case where a description unique to a batch lot is required, the plurality of substrates W are referred to as a batch lot.

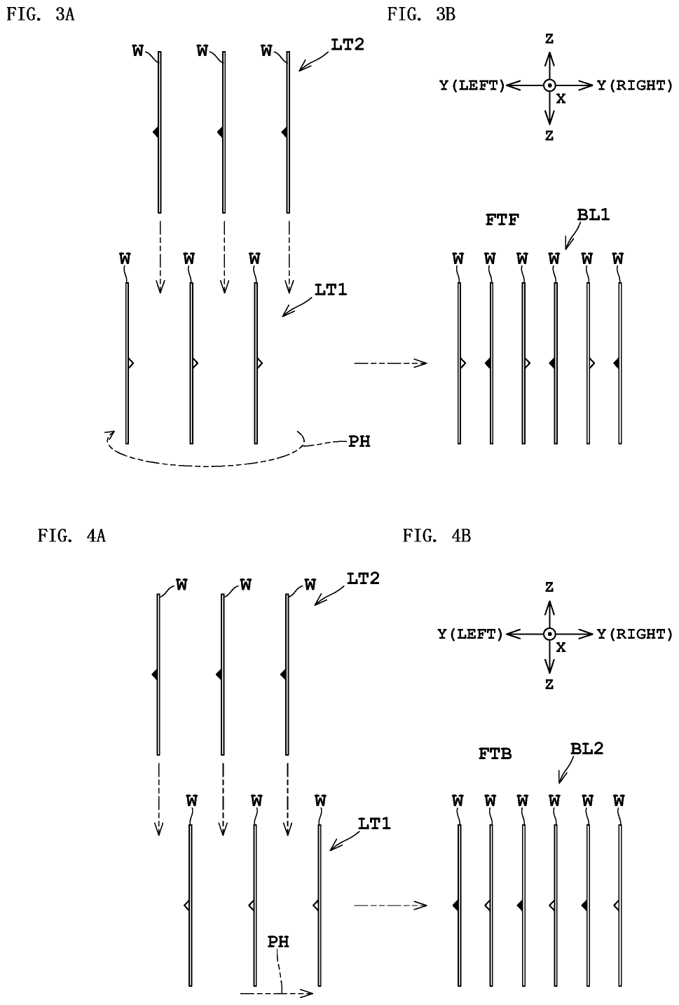

Here, refer to FIGS. 3A and 3B and FIGS. 4A and 4B. FIGS. 3A and 3B and FIGS. 4A and 4B are schematic diagrams for explaining a way of matching processing surfaces constituting the batch lot. In FIGS. 3A and 3B and FIGS. 4A and 4B, each lot includes three substrates W in order to facilitate understanding of the invention.

The transfer mechanism CTC described above assembles the batch lot as illustrated in FIGS. 3A and 3B and FIGS. 4A and 4B.

### (1) Face-to-Face Matching (Face to Face)

As illustrated in FIG. 3A, a batch lot BL1 of the face-to-face matching FTF illustrated in FIG. 3B is assembled by matching one lot LT1 and another lot LT2. Specifically, the processing surface of each substrate W of the lot LT1 is directed, for example, to the left side Y immediately after the posture is turned into the vertical posture by the turning mechanism HVC. For example, the lot LT1 is rotated by 180 degrees about the vertical axis by the pusher PH. As a result, the processing surfaces of the lot LT1 is directed to the right side Y. Each substrate W of the lot LT2 has a processing surface facing the opposite side to the processing surface of the lot LT1, that is, the left side Y. The processing surface of each substrate W in the lot LT1 is marked with a white triangle. The processing surface of each substrate W in the lot LT2 is marked with a black triangle. Here, the processing surface refers to the surface to be processed after the posture is turned into the horizontal posture in the posture turning block 15. The processing surface is the surface facing upward when the substrate W is placed. The processing surface may also be referred to as a main surface, a front surface, or a back surface.

The order of carrying the lot LT1 and the lot LT2 into the transfer mechanism CTC may be reversed. As a result, in FIG. 3B, the odd number of the sequence in the batch lot BL1 can be set as the lot LT1.

### (2) Face-to-Back Matching (Face to Back)

As illustrated in FIG. 4A, one lot LT1 and another lot LT2 are matched to assemble a batch lot BL2 of a face-to-back matching FTB illustrated in FIG. 4B. Specifically, each substrate W of the lot LT1 and the lot LT2 has a processing surface facing the left side Y, for example. When a batch lot is assembled with face-to-back matching FTB, only the linear movement of a half pitch in the width direction Y is performed, and the rotation operation by the pusher PH is not performed.

The second transport mechanism WTR is disposed at the left side Y of the transfer mechanism CTC. The second transport mechanism WTR is configured to be movable between the transfer block 13 and the processing block 17. The second transport mechanism WTR is configured to be movable in the front-back direction X. The second transport mechanism WTR includes a pair of hands 27 that transports a lot. The pair of hands 27 includes, for example, a rotary shaft oriented in the width direction Y. The pair of hands 27 swings around the rotary shaft. The pair of hands 27 clamps the side end surfaces located in the front-back direction X of the plurality of substrates W constituting the lot. The second transport mechanism WTR transfers the plurality of substrates W constituting the lot between the transfer mechanism CTC. The second transport mechanism WTR transfers a plurality of unprocessed substrates W constituting a lot to the processing block 17. The second transport mechanism WTR transfers the plurality of substrates W processed in the processing block 17 between the posture turning block 15.

Here, the processing block 17 will be described before describing the posture turning block 15.

### 6. Processing Block

Refer to FIGS. 1 and 2. The processing block 17 includes, for example, a batch processing unit BPU. For example, the batch processing unit BPU includes six processing units. Specifically, the batch processing unit BPU includes a first batch processing unit BPU1, a second batch processing unit BPU2, a third batch processing unit BPU3, a fourth batch processing unit BPU4, a fifth batch processing unit BPU5,and a sixth batch processing unit BPU6. The number of the batch processing units BPU is not limited to six. That is, the number of batch processing units BPU may be less than six, or may be seven or more.

The first batch processing unit BPU1 to the sixth batch processing unit BPU6are arranged in a line in the front-back direction X. Each of the first batch processing unit BPU1 to the sixth batch processing unit BPU6 includes a processing tank BB and a lifter LF. The processing tank BB stores the processing liquid. The processing liquid is pure water or a chemical liquid. The chemical liquid is, for example, an organic solvent or an etching liquid. The organic solvent is, for example, isopropyl alcohol (IPA). The etching solution is, for example, a phosphoric acid solution.

The lifter LF moves up and down between a processing position inside the processing tank BB and a transfer position above the liquid level of the processing tank BB. The lifter LF transfers the plurality of substrates W to the second transport mechanism WTR at the transfer position. The first batch processing unit BPU1 to the sixth batch processing unit BPU6 are associated with each pair, for example. Specifically, the first batch processing unit BPU1 and the second batch processing unit BPU2 form one pair, the third batch processing unit BPU3 and the fourth batch processing unit BPU4 form one pair, and the fifth batch processing unit BPU5 and the sixth batch processing unit BPU6 form one pair. For example, one pair is divided into a role of chemical liquid processing and a role of cleaning processing. The first batch processing unit BPU1 to the sixth batch processing unit BPU6 can collectively process, for example, up to fifty substrates W. In other words, the first batch processing unit BPU1 to the sixth batch processing unit BPU6 can simultaneously process, for example, at most one batch lot.

The processing liquid is supplied from below to each processing tank BB. In each processing tank BB, the processing liquid is discharged beyond the upper edge. Each processing tank BB immerses the plurality of substrates W placed on the lifter LF in the processing liquid. Each lifter LF holds the lower edge of the substrate W in contact with the lower edge. Each lifter LF transfers a plurality of substrates W between the second transport mechanism WTR.

### 7. Posture Turning Block

As illustrated in FIG. 2, the posture turning block 15 includes a 25-piece chuck TFC, a standby tank 31, and a posture turning tank 33. In the drawings being referred for the standby tank 31 and the posture turning tank 33, the liquid level is not illustrated so that each configuration can be easily seen.

The standby tank 31 includes a processing tank BB0 and a lifter LF0. The processing tank BB0 has the same configuration as the processing tank BB provided in the first batch processing unit BPU1 to the sixth batch processing unit BPU6 described above. The lifter LF0 moves up and down between a standby position inside the processing tank BB0 and a transfer position above the liquid level of the processing tank BB0. The standby tank BB0 stores the processing liquid. The processing liquid is, for example, pure water. At the standby position, the entire substrate W placed on the lifter LF0 is immersed in the processing liquid.

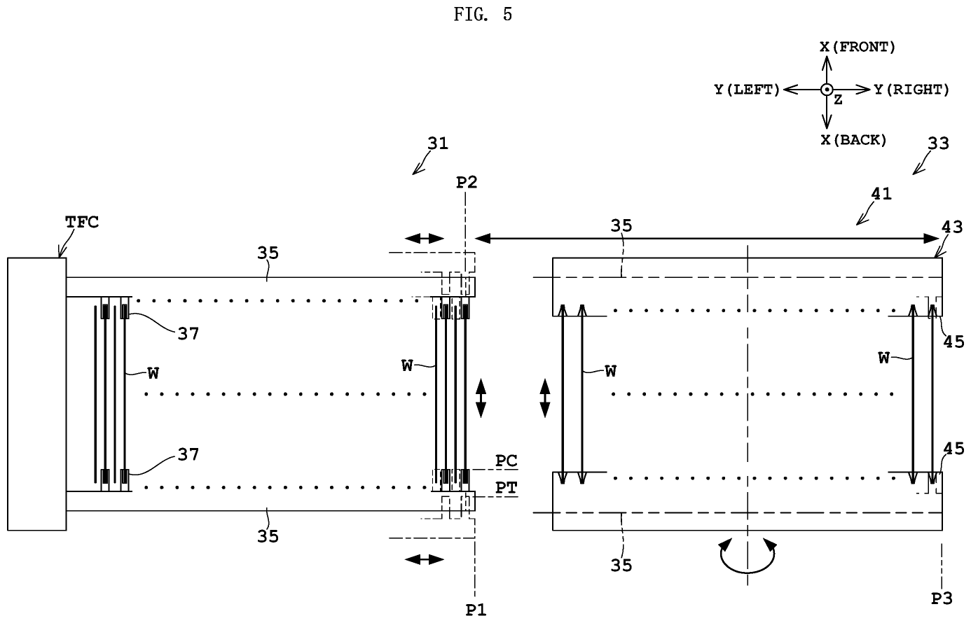

Here, refer to FIG. 5. FIG. 5 is a plan view illustrating a configuration of the 25-piece chuck and the reversing chuck.

The entire 25-piece chuck TFC horizontally moves only in the width direction Y. The 25-piece chuck TFC does not move up and down in the vertical direction Z. The 25-piece chuck TFC does not horizontally move in the front-back direction X. However, the 25-piece chuck TFC opens and closes a hand 35 between a holding position PC and a passing position PT. At the holding position PC, the 25-piece chuck TFC holds the plurality of substrates W. At the passing position PT, the 25-piece chuck TFC does not hold the plurality of substrates W. In other words, the passing position PT allows the lifter LF0 holding the plurality of substrates W to move between the transfer position and the standby position. For example, the 25-piece chuck TFC moves over three positions of a first transfer position P1, a second transfer position P2, and a third transfer position P3 in the width direction Y.

The 25-piece chuck TFC includes locking portions 37. The locking portions 37 are provided inside the hand 35. The locking portions 37 are formed in the width direction Y at intervals of the full pitch described above. The first transfer position P1 and the second transfer position P2 are different in position in the width direction Y by a distance corresponding to a half pitch. The third transfer position P3 is a position where the plurality of substrates W are transferred to the posture turning tank 33. The 25-piece chuck TFC receives only one lot from the lifter LF0 at the first transfer position P1. Specifically, only a plurality of odd-numbered substrates W constituting one lot among two lots constituting the batch lot are received. The 25-piece chuck TFC receives only the other lot from the lifter LF0 at the second transfer position P2. Specifically, only a plurality of even-numbered substrates W constituting the other lot among two lots constituting the batch lot are received.

For example, a plurality of odd-numbered substrates W corresponds to the lot LT2 in the example of FIGS. 3A and 3B described above. A plurality of even-numbered substrates W corresponds to the lot LT1 in the example of FIGS. 3A and 3B described above. For example, a plurality of odd-numbered substrates W corresponds to the lot LT1 in the example of FIGS. 4A and 4B described above. A plurality of even-numbered substrates W corresponds to the lot LT2 in the example of FIGS. 4A and 4B described above.

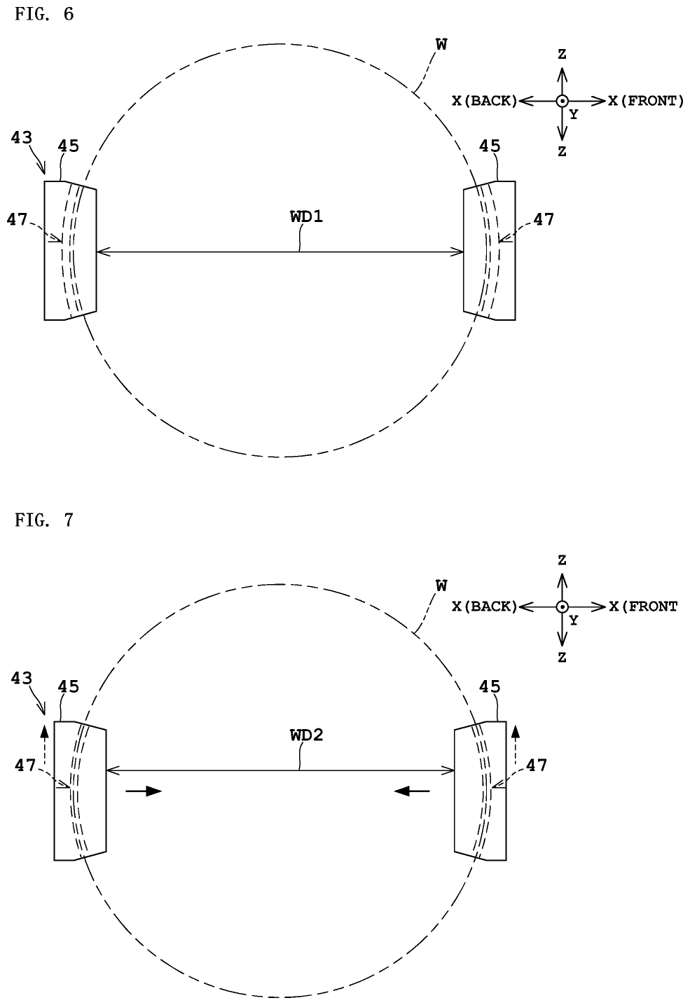

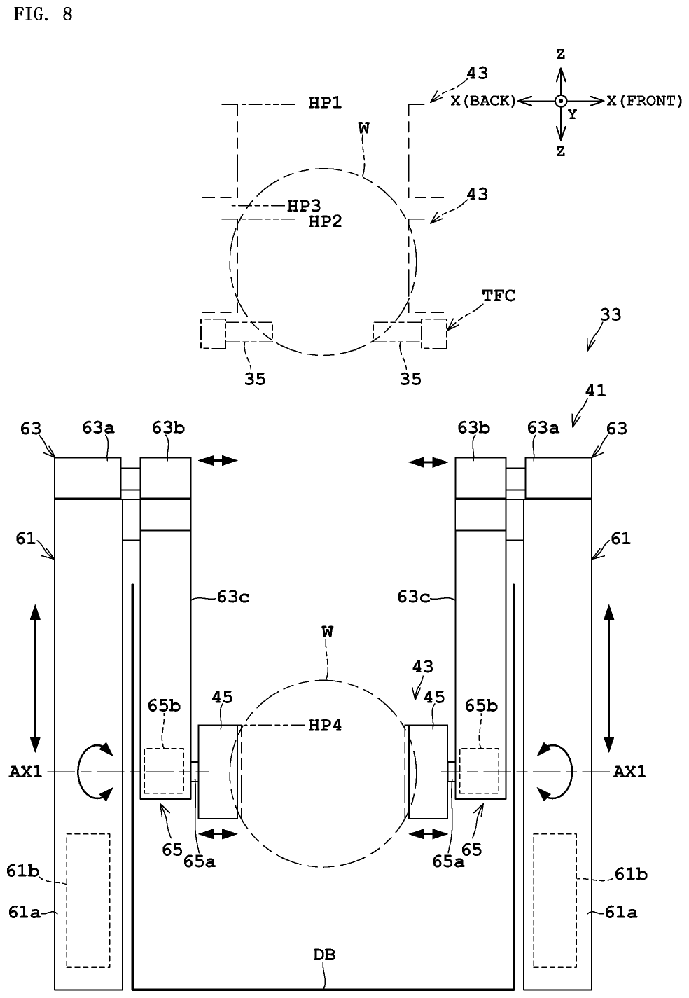

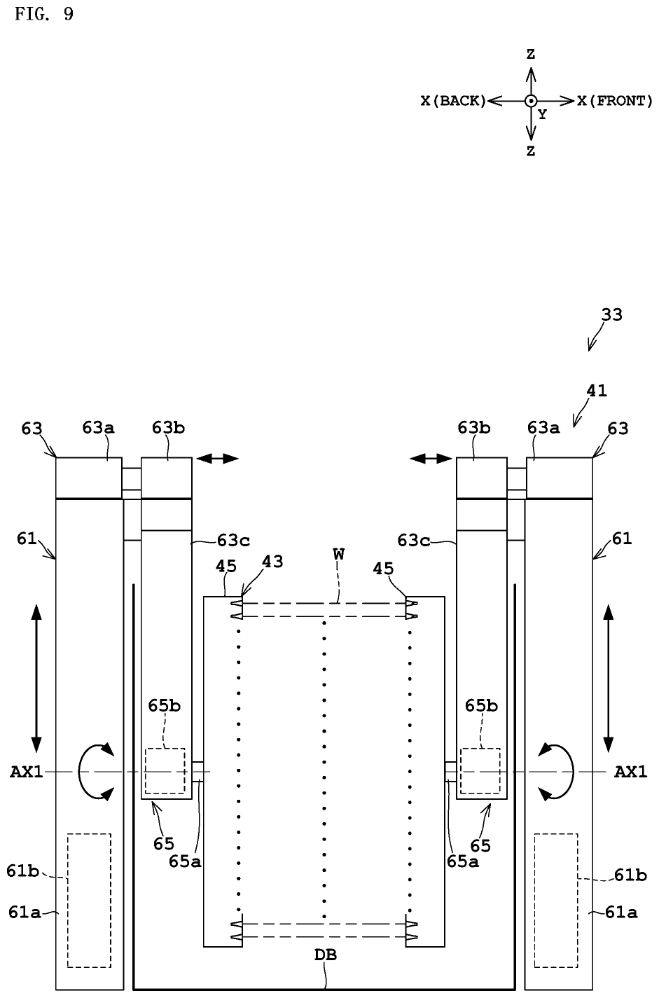

Here, FIGS. 6 to 9 will be further referred to. FIG. 6 is a front view in a state where the reversing chuck is set to an open position. FIG. 7 is a front view in a state where the reversing chuck is set to a holding position. FIG. 8 is a front view illustrating a configuration of the posture turning tank and illustrating a state in which the substrate is held in the vertical posture. FIG. 9 is a front view illustrating a configuration of the posture turning tank and illustrating a state in which the substrate is held in the horizontal posture.

As illustrated in FIGS. 8 and 9, the posture turning tank 33 includes an immersion tank DB and a posture turning unit 41.

First, the main part will be described. The posture turning tank 33 collectively turns the posture of the plurality of substrates W by the reversing chuck 43 in the immersion tank DB. Specifically, the reversing chuck 43 turns the plurality of substrates W from the vertical posture to the horizontal posture. For example, the reversing chuck 43 turns the posture of half of the substrates W constituting the batch lot. For example, the reversing chuck 43 turns the posture of twenty five substrates W. The reversing chuck 43 is disposed to face each other in the radial direction of the substrate W and clamps a peripheral edge portion of the substrate W. The immersion tank DB stores the processing liquid. The processing liquid is, for example, pure water.

As illustrated in FIGS. 6 and 7, the reversing chuck 43 includes a pair of chuck members 45. In the chuck member 45, the length in the vertical direction Z when receiving and holding the substrate W in the vertical posture is shorter than the radius of the substrate W. As illustrated in FIG. 5, in the chuck member 45, the length in the width direction Y when receiving and holding the substrates W in the vertical posture is slightly longer than the length in the alignment direction of the plurality of substrates W in the lot.

As illustrated in FIGS. 6 and 7, each of the chuck members 45 has a groove portion 47 on the opposing surface. The groove portion 47 has an arc shape when viewed from the width direction Y in the vertical posture in which the substrate W in the vertical posture is received and held. The arc shape of the groove portion 47 is a shape along the outer edge of the substrate W.

The pair of chuck members 45 moves in the front-back direction X across a first interval WD1 and a second interval WD2. The pair of chuck members 45 can change the distance between the groove portions 47 facing each other. The first interval WD1 is an interval for transferring the substrates between the 25-piece chuck TFC and the bridging unit 7. The second interval WD2 is an interval that is narrower in the front-back direction X than the first interval WD1 and is for clamping the plurality of substrates W.

The reversing chuck 43 holds only both outermost surfaces of the substrates W in a direction orthogonal to the direction in which the substrates W are transferred. Therefore, when turning the posture of the plurality of substrates W from the vertical posture to the horizontal posture, the reversing chuck 43 does not interfere during transfer even if the substrates W are rotated in any direction. Therefore, the subsequent transfer operation can be smoothly performed.

The posture turning tank 33 includes a lifting mechanism 61, a drive mechanism 63, and a rotating mechanism 65.

The lifting mechanism 61 moves up and down the reversing chuck 43. The drive mechanism 63 opens and closes the reversing chuck 43. The rotating mechanism 65 rotates the reversing chuck 43.

The lifting mechanism 61 is disposed outside the immersion tank DB. The lifting mechanism 61 is disposed along outer surfaces of two side walls provided in the front-back direction X among the four side walls of the immersion tank DB in plan view. As illustrated in FIG. 8, the lifting mechanism 61 is moved up and down over a receiving height HP1, a clamping height HP2, a locking height HP3, and an immersion height HP4 of the reversing chuck 43. The receiving height HP1 is a height for receiving the substrate W in the vertical posture to the reversing chuck 43. The clamping height HP2 is a height for clamping the substrate W in the vertical posture by the reversing chuck 43. The locking height HP3 is a height for locking the substrate W in the vertical posture clamped by the reversing chuck 43. The immersion height HP4 is a height for immersing the substrate W in the vertical posture locked by the reversing chuck 43 in the processing liquid in the immersion tank DB.

The lifting mechanism 61 includes a base member 61a and a lifting motor 61b. The base member 61a is fixed to the bottom of the posture turning tank 33. The lifting motor 61b moves up and down the upper portion of the base member 61a in the vertical direction Z. The lifting motor 61b may be configured by an actuator such as a multistage air cylinder.

The drive mechanism 63 is mounted on an upper portion of the lifting mechanism 61. The drive mechanism 63 includes an air cylinder 63a, a moving piece 63b, and a suspension arm 63c. A working axis of the air cylinder 63a is directed to the front-back direction X. The suspension arm 63c has an inverted L shape. The suspension arm 63c has a horizontal portion attached to an upper portion of the base member 61a. The suspension arm 63c is attached so as to be horizontally movable in the front-back direction X. The drive mechanism 63 moves the suspension arm 63c in the front-back direction X by operating the air cylinder 63a. The drive mechanism 63 drives the reversing chuck 43 by operating the air cylinder 63a. Specifically, the drive mechanism 63 moves the chuck member 45 over the first interval WD1 and the second interval WD2.

For example, the working axis of the air cylinder 63a contracts when not in operation. For example, the working axis of the air cylinder 63a extends during operation. That is, when the air cylinder 63a is not in operation, the reversing chuck 43 is set to the first interval WD1. When the air cylinder 63a is in operation, the reversing chuck 43 is set to the second interval WD2.

The rotating mechanism 65 includes a rotary shaft 65a and a motor 65b.

One end of the rotary shaft 65a is coupled to the outer surface of the chuck member 45. The motor 65b is built in a lower portion of the suspension arm 63c. The motor 65b is disposed in the front-back direction X. The rotary shaft 65a is attached to the suspension arm 63c via a seal member (not illustrated). Therefore, pure water stored in the immersion tank DB does not enter the suspension arm 63c. The motor 65b rotates the rotary shaft 65a about the axis AX1. When the motor 65b is driven, the reversing chuck 43 is rotationally driven around the axis AX1. The rotation of the reversing chuck 43 by the motor 65b can be performed clockwise and counterclockwise around the axis AX1 when viewed from the front side X. The rotation control of the reversing chuck 43 by the motor 65b will be described later in detail.

The posture turning unit 41 configured as described above can turn the posture of the substrate W in a same way as performed by the transfer mechanism CTC. However, the posture turning unit 41 rotates the posture of the surface of the substrate W around the axis AX1 directed to the horizontal direction. The transfer mechanism CTC turns the posture by a combination of the turning mechanism HVC and the pusher PH. Therefore, the posture turning unit 41 can be downsized as compared with the transfer mechanism CTC.

Here, the description returns to FIGS. 1 and 2.

### 8. Bridging Unit

The bridging unit 7 couples the batch type processing apparatus 3 and the single wafer type processing apparatus 5. The bridging unit 7 communicates only with the batch type processing apparatus 3 and the single wafer type processing apparatus 5. The bridging unit 7 includes a bridge robot BR. The bridge robot BR is configured to be movable only in the width direction Y. The bridge robot BR does not move up and down in the vertical direction Z. The bridge robot BR includes a hand 71. The hand 71 is configured to be rotatable in a horizontal plane including the front-back direction X and the width direction Y. The hand 71 is configured to be stretchable in the horizontal direction. The bridge robot BR moves the hand 71 forward and backward so as to receive one substrate in a horizontal posture from the posture turning block 15. The bridge robot BR transfers one substrate set in a horizontal posture to the single wafer type processing apparatus 5.

### 9. Single Wafer Type Processing Apparatus

The single wafer type processing apparatus 5 includes a carry-out block 81, an indexer block 83, and a processing block 85.

### 10. Carry-Out Block

The carry-out block 81 includes a carry-out unit 87. The carry-out unit 87 is disposed at the front side X of the single wafer type processing apparatus 5. The carrier C is placed on the carry-out unit 87. The carry-out block 81 includes, for example, four carry-out units 87. The four carry-out units 87 are disposed along the width direction Y. The carry-out unit 87 is also called a load port.

### 11. Indexer Block

The indexer block 83 includes an indexer robot IR. The indexer robot IR includes, for example, an articulated arm 89 and a hand 91. The indexer robot IR does not move in the width direction Y and the front-back direction X. The indexer robot IR bends the articulated arm 89 and moves the hand 91. The indexer robot IR moves up and down the hand 91 in the vertical direction Z. The indexer robot IR can access each cassette C placed on the four carry-out units 87. The indexer robot IR transports one substrate W with the hand 91. The indexer robot IR transports one substrate W from the processing block 85 to the carry-out unit 87.

### 12. Processing Block

The processing block 85 includes four towers TW1 to TW4 and a center robot CR.

The tower TW1 is disposed at the back side X of the indexer block 83. The tower TW1 is disposed adjacent to the indexer block 83. The tower TW1 includes processing chamber-MPCs stacked in the vertical direction Z. The tower TW1 includes, for example, three processing chamber MPCs. Each of the processing chamber-MPCs processes the substrates W one by one. The processing chamber-MPC, for example, performs drying processing on the substrate W.

The tower TW2 is disposed at the back side X of the tower TW1. The tower TW2 is disposed adjacent to the tower TW1. The tower TW2 has the same configuration as the tower TW1. That is, the tower TW2 includes three processing chamber-MPCs stacked in the vertical direction Z.

The tower TW3 is disposed at the left side Y of the tower TW2. The tower TW3 is disposed at the left side Y of the tower TW2 with the center robot CR interposed therebetween. The tower TW3 also has the same configuration as the towers TW1 and TW2. That is, the tower TW3 includes three processing chambers MPCs stacked in the vertical direction Z.

The tower TW4 is partially different in configuration from the towers TW1 to TW4. That is, the tower TW4 includes the processing chamber-MPCs at the bottom and the top in the vertical direction Z. The tower TW4 includes a transfer unit 93 at the central portion in the vertical direction Z. One substrate W is placed on the transfer unit 93. The transfer unit 93 includes a lifting pin 93a. The lifting pin 93a is moved up and down when the substrate W is received from the bridge robot BR. One substrate W is placed on the transfer unit 93 from the bridge robot BR. In the transfer unit 93, one placed substrate W is received by the center robot CR.

The center robot CR is configured to be movable in the front-back direction X. The center robot CR includes a hand 95. The hand 95 moves up and down in the vertical direction Z. The hand 95 is configured to be rotatable in a plane including the front-back direction X and the width direction Y. The hand 95 is moved so as to be able to access the processing chamber-MPC and the transfer unit 93 of the towers TW1 to TW4. That is, the center robot CR can freely move the hand 95 in the vertical direction Z, the front-back direction X, and the width direction Y. The center robot CR transfers the processed substrate W to the indexer robot 83.

### 13. Control System

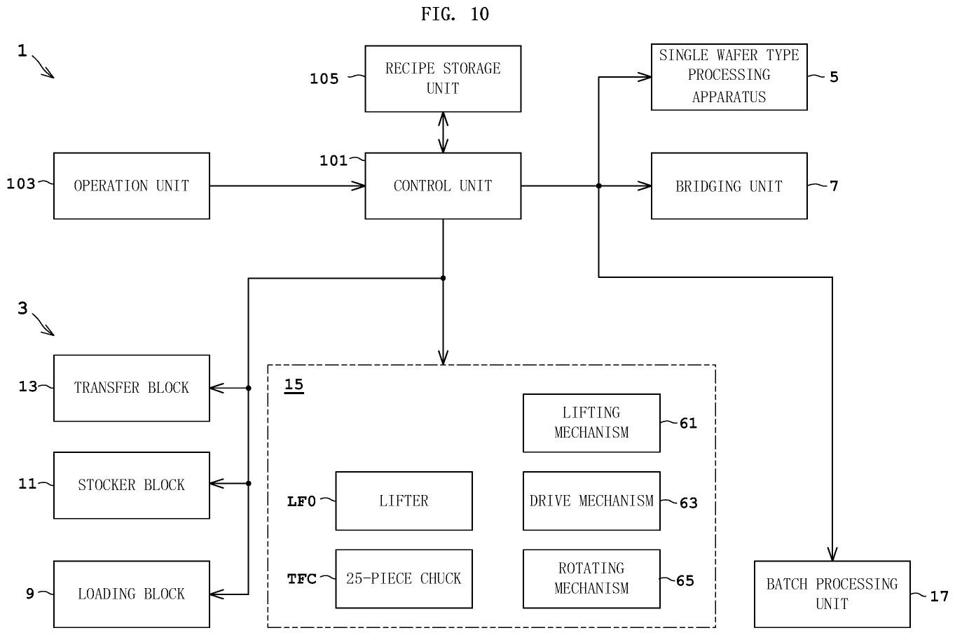

Here, refer to FIG. 10. FIG. 10 is a block diagram illustrating a control system.

The substrate processing apparatus 1 includes a control unit 101. The control unit 101 includes a CPU and a memory. The control unit 101 includes an electronic circuit. The control unit 101 operates the above-described units according to a program stored in advance. The control unit 101 is connected to an operation unit 103. For example, as illustrated in FIG. 1, the operation unit 103 is attached to the front side X of the batch type processing apparatus 3. The operation unit 103 includes, for example, a keyboard, a pointing device, and a display unit, or a touch display panel. The operation unit 103 is operated by an operator of the substrate processing apparatus 1. The operator operates the operation unit 103 to designate a desired recipe for each lot, for example. The operator operates the operation unit 103 to designate a desired matching of processing surfaces for the batch lot, for example. As described above, there are two types of matching the processing surfaces, that is, face-to-face matching (also referred to as “face-to-face”) and face-to-back matching (also referred to as “face-to-back”).

A recipe storage unit 105 is connected to the control unit 101. The recipe storage unit 105 includes a memory. The recipe storage unit 105 stores a recipe defining how to process each lot. The recipe can also be edited by the operator via the operation unit 103. The way of matching the processing surfaces for the batch lot described above is associated with, for example, a recipe. That is, when the recipe is designated for each lot by the operation unit 103, the face-to-face matching and the face-to-back matching are designated for the batch lot for matching the lot and the lot.

In the configuration in which the substrate processing apparatus 1 is connected to the network in the factory, the way of matching the processing surfaces for the batch lot may be designated in advance by a host computer (not illustrated). The host computer (not illustrated) can comprehensively manage not only the substrate processing apparatus 1 but also all devices in the factory or a clean room. In addition, there is a case where a recipe is specified in advance in the host computer for each lot.

The control unit 101 operates the rotating mechanism 65 in the posture turning block 15 according to the recipe of the lot constituting the batch lot, that is, the way of matching the processing surfaces of the batch lot. Details thereof will be described later.

### 14. Description of Operation

An example of processing by the substrate processing apparatus 1 will be described with reference to FIGS. 1 and 2.

First, an overall outlined processing flow will be described.

### 15. Batch Processing

The carrier C accommodating a plurality of unprocessed substrates W is placed on the charging unit 19. At this time, for example, the operator can designate the recipe for the lot of the carrier C by operating the operation unit 103 as necessary. Here, it is assumed that a recipe has already been designated for the carrier C and a way of matching processing surfaces for a batch lot has been designated. That is, the recipe is associated with the carrier C constituting the lot, and the way of matching the processing surfaces for the batch lot is associated with the recipe. In other words, how the batch lot is assembled is associated with the recipe. The way of matching the processing surfaces for the recipe and the batch lot is referred to by the control unit 101. The control unit 101 refers to the recipe storage unit 105 and operates each unit according to the corresponding recipe. In particular, the control unit 101 operates the posture turning unit 41 of the posture turning block 15 on the basis of the way of matching the batch lots associated with the recipe. Although details will be described later, the rotating mechanism 65 of the posture turning block 15 is operated according to the posture of the processing surfaces of the substrates W constituting the lot.

The carrier C is carried into the stocker block 11 by the transport mechanism 23. Two sets of the plurality of substrates W are assembled as a batch lot by the first transport mechanism HTR and the transfer mechanism CTC. The plurality of substrates W constituting the batch lot are transported to the processing block 17 by the second transport mechanism WTR. In the processing block 17, for example, the etching processing with phosphoric acid is performed in the second batch processing unit BPU2. Thereafter, the plurality of substrates W constituting the batch lot are subjected to pure water cleaning processing by the first batch processing unit BPU1. Next, the plurality of substrates W constituting the batch lot are transported to the posture turning block 15 by the second transport mechanism WTR. In the posture turning block 15, only one of the batch lots is transported to the posture turning tank 33. In the posture turning tank 33, only one of the batch lots turns the posture of the plurality of substrates W in the vertical posture to the horizontal posture in the liquid. Thereafter, the plurality of substrates W constituting one lot of the batch lot are sequentially transported one by one to the single wafer type processing apparatus 5. Thereafter, the posture of another one of the batch lots is similarly turned, and then transported to the single wafer type processing apparatus 5.

### 16. Single Wafer Processing

The one substrate W turned to the horizontal posture is transported to the single wafer type processing apparatus 5 by the bridge robot BR. Specifically, one substrate W is placed on the transfer unit 93. One substrate W placed on the transfer unit 93 is received by the center robot CR. The center robot CR carries one substrate W into, for example, the processing chamber-MPC of the tower TW1. In the processing chamber-MPC, for example, the substrate W is subjected to a drying processing. Specifically, for example, pure water is supplied while rotating the substrate W. Thereafter, IPA is supplied to the substrate W to replace pure water of the substrate W with IPA.

Thereafter, the substrate W is rotated at a high speed and dried. In addition, it is preferable to perform a drying processing with carbon dioxide of the supercritical fluid in another processing chamber MPC as necessary. The finish drying processing is performed on the substrate W by the drying processing with the supercritical fluid. As a result, the substrate W is completely dried, but collapse of the pattern formed on the substrate W is suppressed.

One substrate W subjected to the drying processing is carried out to the carry-out unit 87 via the center robot CR and the indexer robot IR. The indexer robot IR accommodates one substrate W in the carrier C placed on the carry-out unit 87. The substrates W constituting the same lot to be processed subsequently are housed in the same carrier C.

### 17. Posture Turn Processing

Although the above is an outlined processing flow by the substrate processing apparatus 1, the posture turning will be described below.

The plurality of substrates W constituting the batch lot subjected to the batch processing are transferred to the lifter LF0 of the standby tank 31 by the second transport mechanism WTR. The lifter LF0 moves the plurality of substrates W constituting the batch lot to the standby position inside the standby tank 31. Since the plurality of substrates W constituting the batch lot stand by in this state, drying can be prevented. That is, collapse of a pattern or the like formed on the substrate W after batch processing can be prevented.

The 25-piece chuck TFC is located, for example, at the second transfer position P2. The 25-piece chuck TFC opens the hand 35. That is, in the 25-piece chuck TFC, the hand 35 is at the passing position PT (refer to FIG. 5). The lifter LF0 is moved up to the transfer position above the liquid level of the standby tank BB0. At this time, since the hand 35 is at the passing position PT in the 25-piece chuck TFC, the plurality of substrates W can pass between the 25-piece chucks TFC and move up. At the same time, the reversing chuck 43 is moved up to the receiving height HP1 by the posture turning unit 41 in the posture turning tank 33 (refer to FIG. 8).

The 25-piece chuck TFC closes the hand 35. That is, in the 25-piece chuck TFC, the hand 35 is at the holding position PC (refer to FIG. 5). In this state, the lifter LF0 is moved down to the standby position. As a result, among the plurality of substrates W of the batch lot placed on the lifter LF0, only the plurality of even-numbered substrates W constituting one lot are placed on the 25-piece chucks TFC. Among the plurality of substrates W of the batch lot placed on the lifter LF0, the plurality of odd-numbered substrates W constituting another lot descends into the standby tank BB0 together with the lifter LF0. As a result, the hand 35 of the 25-piece chuck TFC is set to the first transfer position PT1, which allows the odd-numbered substrates W to standby in a state being prevented from drying until they are moved to the posture turning tank 33. Therefore, pattern collapse due to drying of the plurality of substrates W constituting another lot can also be prevented.

As illustrated in FIG. 5, the 25-piece chuck TFC advances the hand 35 toward the right side Y up to the third transfer position P3. At this time, as illustrated in FIG. 8, since the reversing chuck 43 is positioned at the receiving height HP1, interference with the substrate W does not occur.

The reversing chuck 43 is set to the first interval WD1 (refer to FIG. 6). In this state, the reversing chuck 43 is moved down to the plurality of substrates W placed on the 25-piece chuck TFC. Specifically, as illustrated in FIG. 8, the reversing chuck 43 is moved down to the clamping height HP2. The plurality of substrates W are accommodated in the reversing chuck 43.

The reversing chuck 43 has the second interval WD2 (refer to FIG. 7). As a result, the substrates W accommodated in the reversing chuck 43 are clamped. Further, as illustrated in FIG. 8, the reversing chuck 43 is moved up to the locking height HP3. As a result, among lower edge portions of the end surfaces of the substrates W clamped by the reversing chuck 43, the lower edge portions being located lower than the edge portions laterally outermost sides, abut on and are locked. The 25-piece chuck TFC is moved to the second transfer position P2 in a state where the reversing chuck 43 is temporarily moved up to the receiving height HP1. As a result, the 25-piece chuck TFC is ready to receive the plurality of substrates W constituting another lot placed on the lifter LF0.

As illustrated in FIG. 8, the reversing chuck 43 is moved down to the immersion height HP4. As a result, the plurality of substrates W clamped by the reversing chuck 43 are immersed in the processing liquid in the immersion tank DB. The entirety of the plurality of substrates W is immersed under the processing liquid in the immersion tank DB. In the posture turning block 15, the plurality of substrates W constituting one lot are in a state of being exposed from the liquid for a short time until being raised from the standby tank BB0 and immersed in the immersion tank DB.

For example, the reversing chuck 43 is rotated by 90°. More specifically, in this example, it is rotated counterclockwise by 90°. The rotation direction may be determined by in which direction the processing surface (front face) of the substrate W is located. That is, the rotation direction may be determined such that the processing surface of the substrate W faces upward. As a result, the plurality of substrates W are turned to the horizontal posture.

The reversing chuck 43 is moved upward. Specifically, the reversing chuck 43 is moved upward such that only the substrate W clamped by the uppermost groove portion 47 of the reversing chuck 43 is exposed from the liquid in the immersion tank DB. The height of the reversing chuck 43 is as high as the hand 71 of the bridge robot BR can enter a position slightly separated downward from the lower surface of the substrate W exposed from the liquid.

The hand 71 of the bridge robot BR enters the posture turning unit 41. The hand 71 enters a position slightly separated downward from the lower surface of the substrate W.

The reversing chuck 43 is moved downward. The substrate W is transferred to the hand 71 by the movement of the reversing chuck 43.

The bridge robot BR moves the hand 71 to the right side Y to remove the uppermost substrate W from the reversing chuck 43.

The bridge robot BR rotates the hand 71 to position the substrate W at the right side Y. Specifically, the hand 71 is rotated to move the substrate W toward the transfer unit 93. Then, one substrate W is transferred to the transfer unit 93.

By the operation of the posture turning block 15 described above, one substrate W is transported in a horizontal posture from the batch type processing apparatus 3 to the single wafer type processing apparatus 5.

### 18. Detailed Operation of Posture Turn Processing

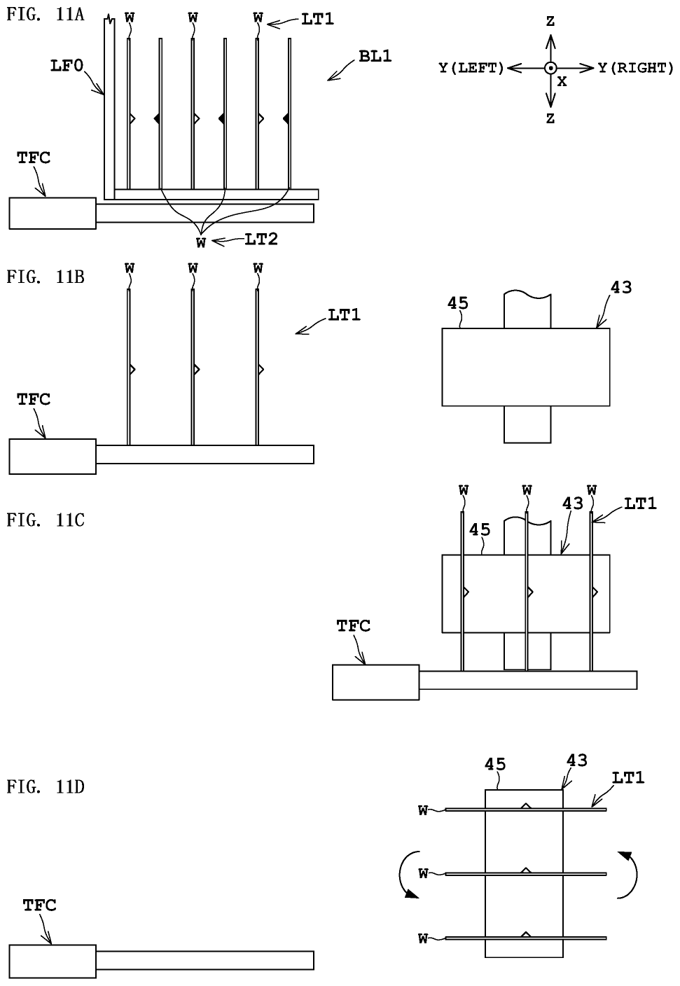

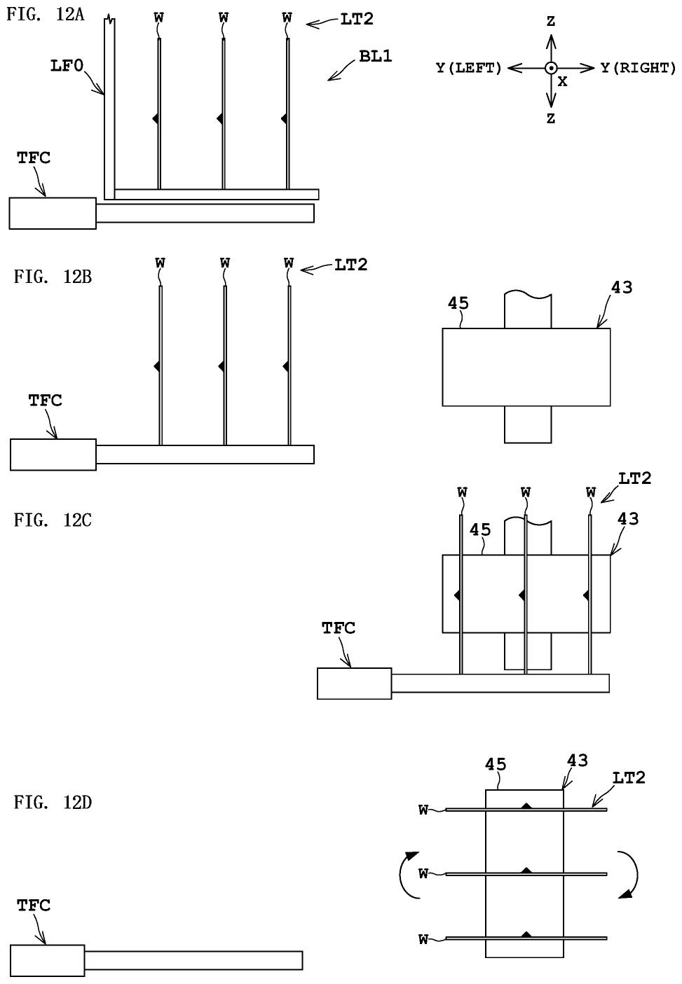

Here, a detailed operation of the above-described posture turn processing will be described. Hereinafter, FIGS. 11A to 11D and FIGS. 12A to 12D will be referred to. FIGS. 11A to 11D and FIGS. 12A to 12D are schematic diagrams illustrating an example of posture turn in the batch lot of face-to-face matching. Here, the batch lot BL1 described with reference to FIGS. 3A and 3B will be described as an example. The batch lot BL1 is a combination of lot LT1 and lot LT2 in a face-to-face matching FTF.

As illustrated in FIGS. 11A and 11B, the 25-piece chuck TFC receives, for example, a plurality of substrates W constituting the lot LT1 from the batch lot BL1 held by the lifter LF0. Each substrate W constituting the lot LT1 has a processing surface facing the right side Y, for example. Next, as illustrated in FIG. 11C, the reversing chuck 43 receives each substrate W constituting the lot LT1 from the 25-piece chuck TFC.

Next, the control unit 101 operates the rotating mechanism 65 on the basis of the way of matching the lots associated with the recipe at this time. In this case, since the batch lot BL1 is the face-to-face matching FTF, the control unit 101 can know in which posture the processing surface of each substrate W constituting the lot LT1 is held by the reversing chuck 43. The control unit 101 operates the rotating mechanism 65 so that the processing surface faces upward.

Specifically, as illustrated in FIG. 11D, the control unit 101 rotates the rotating mechanism 65 counterclockwise by a predetermined angle as viewed from the back side X. The predetermined angle is, for example, 90 degrees. That is, the control unit 101 rotates the rotating mechanism 65 by 90 degrees in one direction.

The control unit 101 performs posture turning on the remaining lot LT2 of the batch lot BL1. Specifically, as illustrated in FIGS. 12A and 12B, the 25-piece chuck TFC receives the plurality of substrates W constituting the lot LT2 held by the lifter LF0. Next, as illustrated in FIG. 12C, the reversing chuck 43 receives each substrate W constituting the lot LT2 from the 25-piece chuck TFC. The lot LT2 is in a state in which the processing surface faces the left side Y.

Next, the control unit 101 operates the rotating mechanism 65 so that the processing surface of the lot LT2 faces upward. Specifically, as illustrated in FIG. 12D, the control unit 101 rotates the rotating mechanism 65 clockwise only by a predetermined angle as viewed from the back side X. The predetermined angle is, for example, 90 degrees. That is, the control unit 101 rotates the rotating mechanism 65 only by 90 degrees in the other direction that is opposite to the one direction.

The correspondence relationship between the configurations of the present invention and the above-described embodiments is as follows.

The batch type processing apparatus 3 corresponds to a “batch type processing unit” in the present invention. The single wafer type processing apparatus 5 corresponds to a “single wafer type processing unit” in the present invention. The posture turning tank 33 corresponds to an “posture turning unit” in the present invention. The 25-piece chuck TFC corresponds to a “first transport unit” in the present invention. The bridge robot BR corresponds to a “second transport unit” in the present invention. The drive mechanism 63 corresponds to an “opening/closing drive mechanism” in the present invention. The rotating mechanism 65 corresponds to a “rotary drive mechanism” in the present invention. The first interval WD1 corresponds to an “open position” in the present invention. The second interval WD2 corresponds to a “holding position” in the present invention.

According to the present embodiment, the control unit 101 operates the drive mechanism 63 to cause the reversing chuck 43 to hold the plurality of substrates W in the vertical posture. Thereafter, when turning the posture of the plurality of substrates W from the vertical posture to the horizontal posture, the control unit 101 operates the rotating mechanism 65 so that the processing surfaces of the plurality of substrates W face upward. Therefore, regardless of the posture of the processing surfaces of the substrates W, posture turn can be properly performed such that the processing surfaces of the plurality of substrates W face upward.

In addition, the plurality of substrates W in the vertical posture have the processing surfaces directed in one direction or the other direction. Therefore, the control unit 101 can cause the processing surfaces of the plurality of substrates W to face upward by operating the rotating mechanism 65 to rotate by 90 degrees in the other direction or one direction according to the posture of the processing surfaces.

When the target of posture turn is the batch lot BL2 illustrated in FIGS. 4A and 4B, that is, the batch lot BL2 of the face-to-back matching FTB in which the processing surfaces are directed to the left side Y, first, the control unit 101 operates the rotating mechanism 65 so that the processing surfaces of the substrates W face upward for the lot LT1, and rotates the substrates W by 90 degrees in one direction. Next, the control unit 101 operates the rotating mechanism 65 to rotate the lot LT2 by 90 degrees in one direction such that the processing surfaces of the substrates W face upward. When the processing surface of each substrate W of the batch lot BL2 is directed to the right side Y, the control unit 101 operates the rotating mechanism 65 so that the processing surface of the substrate W is directed upward, and rotates the substrate W by 90 degrees in the other direction.

The present invention is not limited to the embodiment described above, but may be modified as follows.
(1) In the above-described embodiment, the control unit 101 operates the rotating mechanism 65 in the opposite direction in the lot BL1 and the lot BL2 when turning the posture of the batch lot BL1. However, the present invention is not limited to such rotation control. For example, the rotating mechanism 65 may be operated as follows.

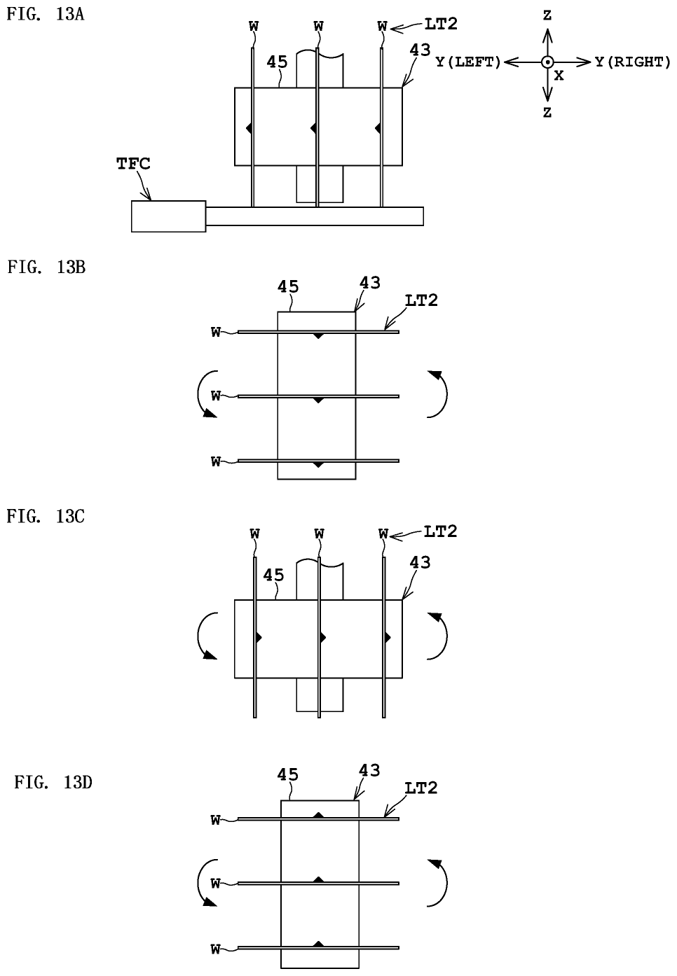

Here, refer to FIGS. 13A to 13D. FIGS. 13A to 13D are schematic diagrams illustrating another example of posture turn.

In the above-described example, the control unit 101 operates the rotating mechanism 65 in one direction or the other direction which is the opposite direction according to the posture of the processing surfaces of the lots LT1 and LT2. However, the control unit 101 may operate the rotating mechanism 65 as follows.

The control unit 101 operates the rotating mechanism 65 to rotate the lot LT2 only in one direction. That is, the control unit 101 operates the rotating mechanism 65 for the lot LT1 to rotate the lot LT1 by the first angle in one direction. The first angle is, for example, 90 degrees. The control unit 101 operates the rotating mechanism 65 to rotate the lot LT2 in one direction by the second angle so that the processing surface of the substrate W faces upward. The second angle is greater than the first angle. The second angle is, for example, 270 degrees. That is, regardless of the lots LT1 and LT2, the control unit 101 rotates the rotating mechanism 65 only in the same direction so that the processing surface of the substrate W faces upward.

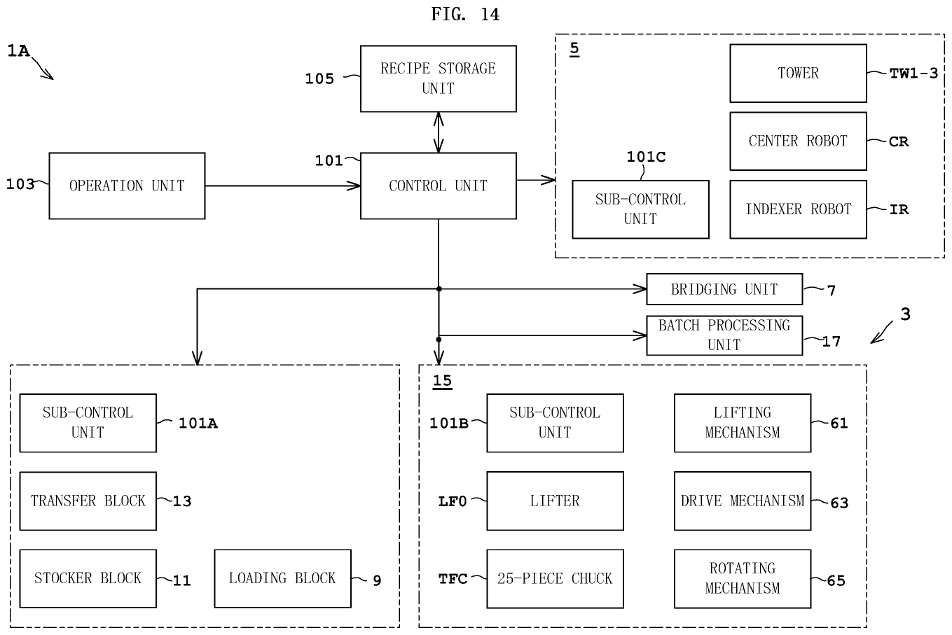

As described above, the control unit 101 operates the rotary drive mechanism 65 so as to rotate the plurality of substrates W by 90 degrees or 270 degrees in one direction, so that the processing surfaces of the plurality of substrates W can be directed upward. Therefore, the control of the drive mechanism 65 by the control unit 101 can be simplified.
(2) In the above-described embodiment, the substrate processing apparatus 1 includes one control unit 101, and the control unit 101 integrally controls each unit. However, the present invention is not limited to such a control system. Here, refer to FIG. 14. FIG. 14 is a block diagram illustrating a modification of the control system.

That is, a substrate processing apparatus 1A includes a control unit 101 that controls the entire apparatus, a sub-control unit 101A that controls the batch type processing apparatus 3, a sub-control unit 101B that controls the posture turning block 15, and sub-control units 101C that control the single wafer type processing apparatus 5.

According to such a configuration, the control unit 101 transmits the recipe for each lot to the sub-control units 101 A, 101B, and 101 C. The control unit 101 also transmits information on the way of matching the processing surfaces regarding the batch lot. For example, the sub-control unit 101A operates the rotational movement and the linear movement of the pusher PH in the posture turning block 13 according to the recipe of the lot constituting the batch lot received from the control unit 101. For example, the sub-control unit 101B operates the rotation direction and angle of the rotating mechanism 65 according to the recipe of the lot constituting the batch lot received from the control unit 101. For example, the sub-control unit 101C controls each tower TW1 to 3 according to the recipe of the lot constituting the batch lot received from the control unit 101.

According to such a configuration, the load of the control unit 101 can be distributed by the sub-control units 101A, 101B, and 101C. Therefore, the load on the control unit 101 can be reduced.
(3) In the above-described embodiment, the reversing chuck 43 includes the pair of chuck members 45. However, in the present invention, the reversing chuck 43 is not limited to such a configuration.
(4) In the embodiment described above, the posture turning tank 33 turns the posture of the plurality of substrates W in pure water. However, the present invention does not require posture turn in liquid. That is, the posture turning tank 33 may turn the posture of the plurality of substrates W in air such as air or nitrogen gas. In this case, since the resistance at the time of rotation is small, the speed of posture turn can be increased, and the throughput can be improved.
(5) In the above-described embodiments, the configuration in which the substrate processing apparatus 1 couples the batch type processing apparatus 3 and the single wafer type processing apparatus 5 by the bridging unit 7 has been described as an example. However, the present invention can also be applied to one substrate processing apparatus 1 including the batch type processing apparatus 3 and the single wafer type processing apparatus 5 in the same housing.

The present invention may be embodied in other specific forms without departing from the spirit or essential attributes thereof and, accordingly, reference should be made to the appended claims, rather than to the foregoing specification, as indicating the scope of the invention.

1. A posture turning apparatus that turns a posture of a plurality of substrates, the apparatus comprising:
an reversing chuck that holds the plurality of substrates;
an opening/closing drive mechanism that drives the reversing chuck in a radial direction of the substrates between an open position for transferring the plurality of substrates to and from the reversing chuck and a holding position for holding the plurality of substrates by the reversing chuck;
a rotary drive mechanism that drives the reversing chuck about a horizontal axis in order to turn the posture of the plurality of substrates from a vertical posture to a horizontal posture; and
a control unit that operates the rotary drive mechanism so that processing surfaces of the plurality of substrates face upward, when turning the posture of the plurality of substrates from the vertical posture to the horizontal posture after operating the opening/closing drive mechanism so as to cause the reversing chuck to hold the plurality of substrates in a vertical posture.

2. The posture turning apparatus according to claim 1, wherein the control unit operates the rotary drive mechanism so as to rotate in one direction or another direction opposite to the one direction according to the posture of the processing surfaces of the plurality of substrates.

3. The posture turning apparatus according to claim 1, wherein the control unit operates the rotary drive mechanism so as to rotate only in one direction according to the posture of the processing surfaces of the plurality of substrates.

4. The posture turning apparatus according to claim 1, wherein the reversing chuck holds only both outermost surfaces of the plurality of substrates in a direction orthogonal to a direction in which the plurality of substrates are transferred.

5. The posture turning apparatus according to claim 1, wherein the control unit operates the rotary drive mechanism according to a recipe that defines how to process the plurality of substrates.

6. The posture turning apparatus according to claim 5, wherein among the recipes, for a batch lot configured by matching a certain plurality of substrates and another plurality of substrates, the control unit operates the rotary drive mechanism according to a way of matching the processing surfaces, i.e., to which posture the processing surfaces are matched.

7. The substrate processing apparatus that processes a substrate, the apparatus comprising:
a batch type processing unit that collectively processes a plurality of substrates in a vertical posture;
a single wafer type processing unit that processes one substrate in a horizontal posture;
a posture turning unit that turns the vertical posture to the horizontal posture of the plurality of substrates processed by the batch type processing unit;
a first transport unit that transports the plurality of substrates processed by the batch type processing unit to the posture turning unit; and
a second transport unit that transports the plurality of substrates brought into a horizontal posture by the posture turning unit to the single wafer type processing unit,
wherein the posture turning unit includes,
an reversing chuck that holds the plurality of substrates,
an opening/closing drive mechanism that drives the reversing chuck in a radial direction of the substrates between an open position for transferring the plurality of substrates to and from the reversing chuck and a holding position for holding the plurality of substrates by the reversing chuck, and
a rotary drive mechanism that drives the reversing chuck about a horizontal axis to turn the plurality of substrates from the vertical posture to the horizontal posture.
